(19) United States
(12) Patent Application Publication
(10) Pub. No.: US 2005/0056881 A1
(43) Pub. Date: Mar. 17, 2005

(54) Dummy pattern for silicide gate electrode

(76) Inventors: Yee-Chia Yeo, Hsin-Chu (TW); Chih-Hao Wang, Hsin-Chu (TW); Chenming Hu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/685,938

(22) Filed: Oct. 15, 2003

Related U.S. Application Data
(60) Provisional application No. 60/503,113, filed on Sep. 15, 2003.

(51) Int. Cl. H01L 29/788

(52) U.S. Cl. 257/315

(57) ABSTRACT

A semiconductor device having a plurality of silicided polysilicon structures in which the silicidation of the polysilicon structures is approximately uniform is provided. Dummy polysilicon structures are formed on the substrate prior to silicidation. The dummy polysilicon structures allow the surface of the wafer to be planarized without an excessive recess and causes the amount of metal available for the silicidation process to be approximately uniformly distributed among the various polysilicon structures.

This application claims the benefit of U.S. Provisional Application No. 60/503,113 filed on Sep. 15, 2003, entitled Dummy Pattern for Silicide Gate Electrode, which application is hereby incorporated herein by reference.

### TECHNICAL FIELD

The present invention relates generally to semiconductor devices, and more particularly to semiconductor devices with gate electrodes formed by silicidation.

### BACKGROUND

Complementary metal oxide semiconductor (CMOS) devices, such as metal oxide semiconductor field-effect transistors (MOSFETs), are commonly used in the fabrication of ultra-large scale integrated (ULSI) devices. The continuing trend is to reduce the size of the devices and to lower the power consumption requirements. Size reduction of the MOSFETs has enabled the continued improvement in speed performance, density, and cost per unit function of integrated circuits.

FIG. 1 illustrates one type of a MOSFET formed on a substrate 110. The MOSFET comprises a source 112, a drain 114, and a gate electrode 116. A channel 118 is formed between the source 112 and the drain 114. The gate electrode 116 is formed on a dielectric layer 120. Spacers 122 are formed on each side of the gate electrode 116, and contact pads or contact silicide 124 are formed on the source 112 and the drain 114. Isolation trenches 126 may be used to isolate the MOSFET from other devices (not shown).

As the length of the gate electrode 116 is reduced, the source 112 and drain 114 increasingly interact with the channel 118 and gain influence on the channel potential. Consequently, a transistor with a short gate length suffers from problems related to the inability of the gate electrode 116 to substantially control the on and off states of the channel 118. Phenomena such as reduced gate control associated with transistors with short channel lengths are termed short-channel effects.

One of the primary means by which short-channel effects are kept under control is the downscaling of the gate dielectric thickness in conjunction with transistor size reduction. However, this aggravates the problems of poly-silicon (poly-Si) gate depletion and high gate tunneling leakage current. For example, for the poly-Si gate depletion layer to be less than 25% of the equivalent gate dielectric thickness, the active dopant density in poly-Si must be 1.87×10²⁰ cm⁻³ at a gate electrode length (LG) of 25 nm. This dopant density, however, causes great difficulty because the active dopant density in the poly-Si at the gate-dielectric interface saturates at 6×10¹⁹ cm⁻³ and 1×10²⁰ cm⁻³ for p+ and n+ doped poly-Si, respectively. Insufficient active dopant density in the gate electrode results in a significant voltage drop across the gate depletion layer, and increases the equivalent gate dielectric thickness. In effect, it reduces the gate capacitance in the inversion regime and the inversion charge density or leads to a lower effective gate voltage, and therefore compromises device performance.

Attempts have been made to fabricate a highly conductive gate electrode by performing a silicidation process on the poly-Si gate electrode. Generally, the silicidation reaction converts the poly-Si material to a highly conductive silicide. For example, FIGS. 2a-2b illustrate fabricating a transistor such as that shown in FIG. 1 with a silicided gate electrode. FIG. 2a illustrates the transistor of FIG. 1 with a dielectric layer 230 formed on the source 112 and the drain 114, and a metal layer 232 formed on the gate electrode 116 and the dielectric layer 230. A metal silicided layer 234, which is generally formed when the contact pads 124 are formed, may remain on the gate electrode 116. An anneal process is performed to cause the poly-Si gate electrode to become silicided. The excess metal is removed, thereby providing the structure shown in FIG. 2b, wherein the gate electrode 116 is silicided. A similar method has been described in a paper by B. Tavel et al., entitled “Totally silicided (CoSi₂) polysilicon: a novel approach to very low-resistive gate without metal CMP nor etching,” published in pages 825-828 of the Technical Digest of the 2001 International Electron Device Meeting, held in Washington D.C., USA.

Often, however, it is difficult to silicide transistor gates uniformly throughout a wafer or a chip because the density of the poly-Si structures varies throughout the wafer or chip. For example, FIGS. 3a-3d illustrate cross-section views of a portion of a chip after various process steps that illustrate one particular problem that may cause non-uniform silicidation.

FIG. 3a is a cross-section view of a portion of a semiconductor chip having transistors 304, 306, and 308 with varying gate lengths formed in active regions of the semiconductor chip. The components of the transistors are explained above with reference to FIG. 1. The portion comprises a low poly-Si density region 310 and a high poly-Si density region 312. The low poly-Si density region 310 and the high poly-Si density region 312 may be adjacent to each other (as shown in FIG. 3a) or may be spaced apart on different portions of the wafer or chip.

FIG. 3b is a cross-section view of the portion shown in FIG. 3a after an insulating or dielectric layer 316 is formed over the transistors and a chemical mechanical planarization or chemical mechanical polishing (CMP) process is performed. The CMP process planarizes the surface of the dielectric layer 316 and exposes the gate electrodes 314. As illustrated in FIG. 3b, the CMP often results in a recess 318 in the low poly-Si density region 310. This “dishing” phenomenon is a common artifact of the CMP process in areas with a low density of features such as transistor 308.

FIG. 3c is a cross-section view of the portion shown in FIG. 3b after a metal layer 330 is formed on the dielectric layer 316 and the gate electrodes 116, and an annealing step is in process. The annealing step results in the silicidation of the gate electrodes 116. The silicidation of the gate electrodes 116 occurs to a large extent in the low poly-Si density region 310 because the metal region participating in the silicidation process in the low poly-Si density region 310 is greater than the metal region participating in the silicidation process in the high poly-Si density region 312 due of the difference in the thickness and/or the density. As a result, the rate at which the silicidation front proceeds downwards to consume the poly-Si material differs in regions with different poly-Si densities. In a region with a lower poly-Si density, the silicidation occurs to a greater extent, and the silicidation front is deeper from the initial top surface of the poly-Si material.

For example, the metal participating in the silicidation of transistors 304, 306, and 308 is marked by reference numerals 332, 334, and 336, respectively. As illustrated, the metal participating in the silicidation of transistors 304 and 306 in the high poly-Si density region 312 is less than the metal participating in the silicidation of transistor 308 in the low poly-Si density region 310. Accordingly, the silicidation front 340 of transistor 308 progresses faster than the silicidation front 342 of transistors 304 and 306.

FIG. 3d is a cross-section view of the portion shown in FIG. 3c after the silicidation process is complete. As illustrated in FIG. 3d, the gate electrodes 314 of transistor 308 located in the low poly-Si density region 310, are substantially silicided, but the gate electrodes 314 of transistors 304 and 306 located in the high poly-Si density region 312, are not completely silicided, i.e., the silicidation front 340 of transistor 308 reaches the interface between the gate dielectric and the gate electrode before the silicidation front 342 of transistors 304 and 306. If additional silicidation is performed to cause the gate electrodes 314 of transistors 304 and 306 to be fully silicided, the transistor 308 may suffer from problems related to the excess diffusion of metal atoms through the gate dielectric into the channel region.

Therefore, there is a need for a low-resistance or highly conductive gate electrode, and in particular, for uniformly silicided poly-Si structures.

### SUMMARY OF THE INVENTION

These and other problems are generally reduced, solved or circumvented, and technical advantages are generally achieved, by embodiments of the present invention, which provides a semiconductor device having dummy silicide structures.

In one embodiment of the present invention, a semiconductor device has a first structure that is fully silicided and at least one dummy silicided structure. The first structure may be, for example, a gate electrode of a transistor formed in the active region or the isolation region of the semiconductor device.

In another embodiment of the present invention, a method of manufacturing a semiconductor device having a first fully silicided structure and a fully silicided dummy structure is provided. A first polysilicon structure and a dummy polysilicon structure are provided on a substrate. A metal layer is formed over the first polysilicon structure and the dummy polysilicon structure, and a silicidation process is performed. The first polysilicon structure may be, for example, a gate electrode of a transistor located in the active region or elsewhere.

In yet another embodiment of the present invention, a dielectric layer is formed over a first polysilicon structure and a dummy polysilicon structure. The dielectric layer is planarized such that the first polysilicon structure and the dummy polysilicon structure are exposed. A silicidation process is performed so that the first polysilicon structure and the dummy polysilicon structure are substantially fully silicided.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-section view of a transistor;

FIGS. 2a-2b are cross-section views of a wafer illustrating a process of siliciding a polysilicon gate electrode of a transistor;

FIGS. 3a-3d are cross-section views of a wafer illustrating a process of planarizing and siliciding polysilicon gate electrodes of transistors;

FIGS. 4a-4d are cross-section views of a wafer illustrating a process of forming fully silicided polysilicon gate electrodes in accordance with one embodiment of the present invention;

FIG. 5 is a graph illustrating the silicide thickness as a function of pattern density in accordance with one embodiment of the present invention;

FIGS. 6a-6d are cross-section views of a wafer illustrating a process of fully silicided polysilicon gate electrodes utilizing an etch stop layer in accordance with one embodiment of the present invention; and

FIGS. 7a-7b are cross-section views of a wafer illustrating a process of forming contacts on a semiconductor device having dummy polysilicon structures in accordance with one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. In particular, the method of the present invention is described in the context of forming a gate of a transistor. One of ordinary skill in the art, however, will appreciate that the process described herein may be used for forming any type of device or structure that utilizes silicided polysilicon structures. Accordingly, the specific embodiments discussed herein are merely illustrative of specific ways to make and use the invention, and do not limit the scope of the invention.

While poly-Si gate electrodes are used as an example to illustrate this invention, it is understood that other gate electrodes such as poly-crystalline silicon-germanium gate electrodes, or single-crystalline silicon gate electrodes may be used in place of the poly-crystalline gate electrode described herein.

Generally, it is desirable for the silicidation fronts to progress downwards at approximately equal rates such that all gate electrodes become fully silicided at about the same time. In accordance with one embodiment of the present invention, dummy poly-Si structures are formed to modify the speed at which the silicidation fronts progress in different portions of the semiconductor chip. The introduction of dummy poly-Si structures in low poly-Si density regions reduces the amount of metal participating in the silicidation process of the actual gate electrode and, thus, reduces the speed at which the silicidation front progresses downwards during the silicidation process.

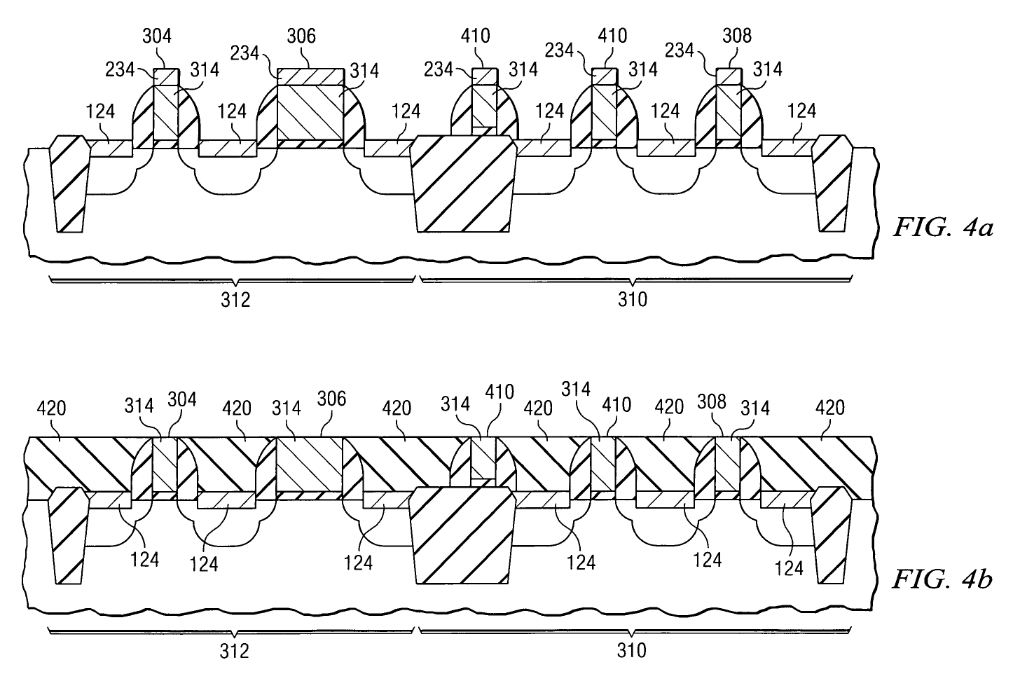

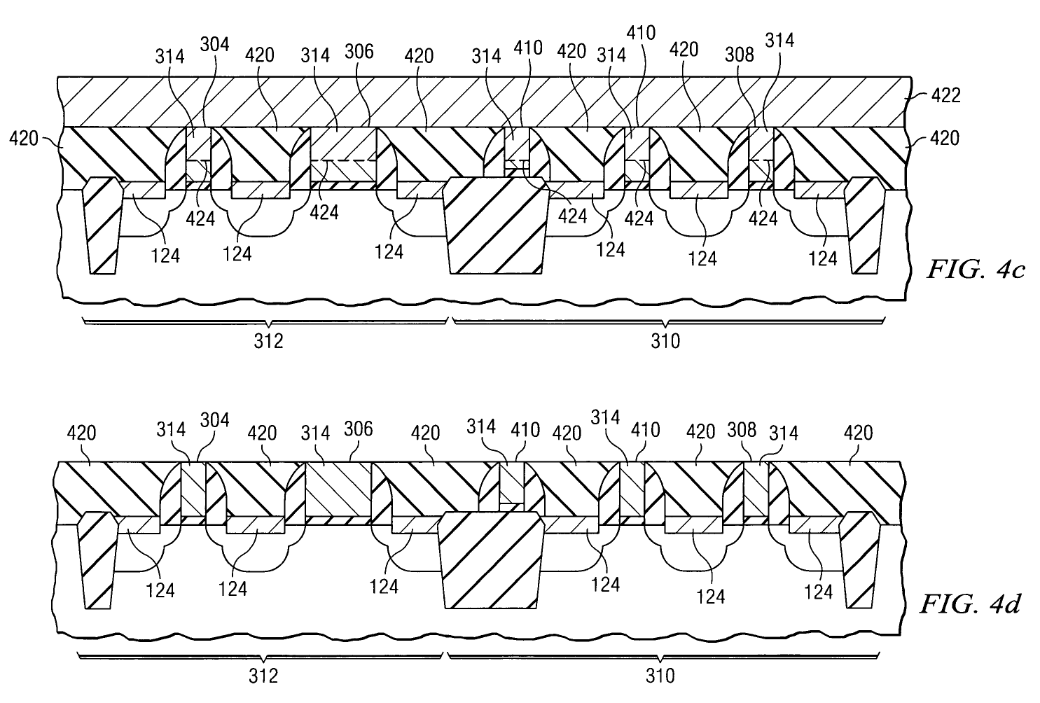

FIGS. 4a-4d illustrate cross-section views of a portion of a semiconductor wafer during various steps of a first method embodiment of the present invention in which dummy poly-Si structures are formed. It should be noted that the dummy poly-Si structures are shown as transistor gates for illustrative purposes only and that other poly-Si structures may be used.

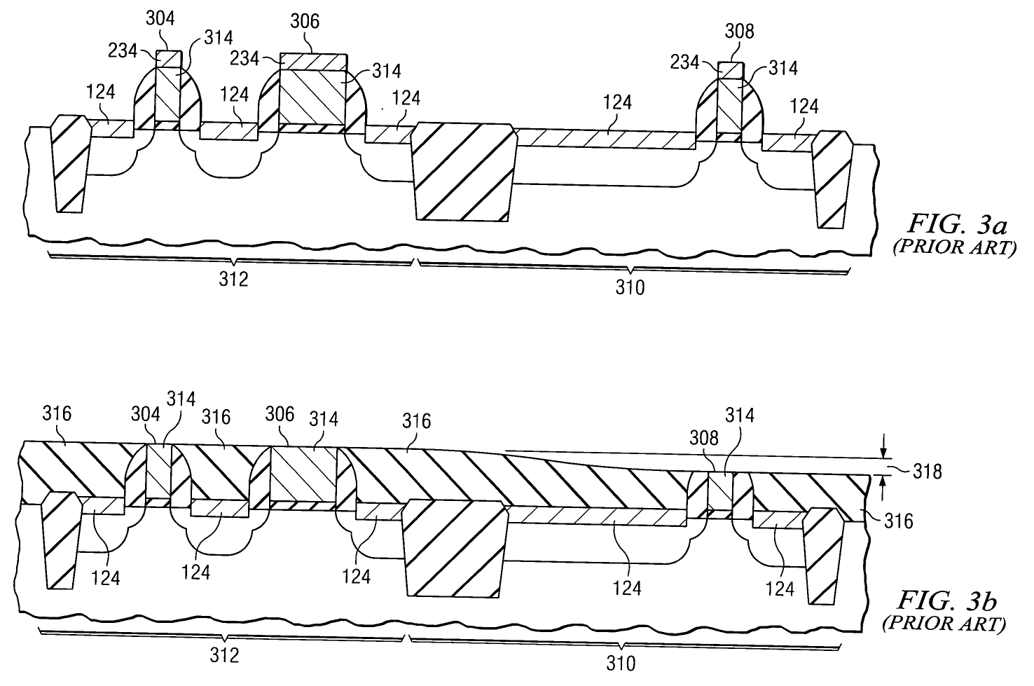

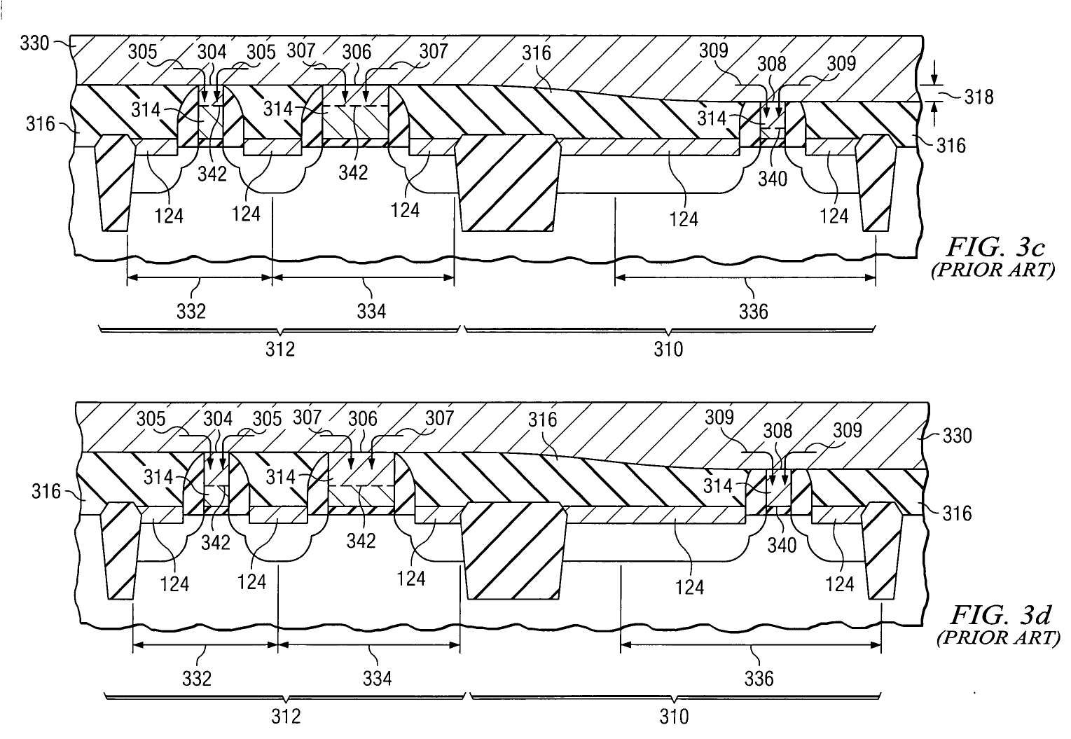

The process begins in FIG. 4a, which illustrates the structure discussed above with reference to FIG. 3a, except that dummy poly-Si structures 410 have been formed. The original metal silicided layer 234 (formed on the gates) may be retained or removed prior to the silicidation process of the gate electrodes.

The dummy poly-Si structures 410 may be formed on an isolation region or in an active region and, preferably, are not connected to other circuitry on the semiconductor chip. In some embodiments, however, they may be electrically tied to a ground node or other reference potential. In other embodiments, the dummy poly-Si structures 410 may be connected to other circuitry on the semiconductor chip, but does not perform a logical function for the circuitry contained on the semiconductor chip.

FIG. 4b illustrates the wafer shown in FIG. 4a after a dielectric layer 420 has been formed and planarized. The dielectric layer 420 may be formed by any method known in the art, such as, for example, by a chemical vapor deposition process. Preferably, planarization is performed by a chemical-mechanical polishing (CMP) using an oxide slurry.

As one of ordinary skill in the art will appreciate, the introduction of dummy poly-Si provides a more uniform surface after the CMP process as compared to the resulting wafer without dummy poly-Si structures as shown in FIG. 3b. In particular, the dummy poly-Si structures reduce the recess associated with the CMP process in the low poly-Si density region 310 by increasing the density of poly-Si structures.

Referring now to FIG. 4c, the wafer of FIG. 4b is shown after a metal layer 422 is formed over the gate electrodes to be silicided and the silicidation process has begun. FIG. 4c illustrates that the silicidation front 424 of the poly-Si gate electrodes 304, 306, and 308 and the dummy poly-Si structures 410 progresses at about equal rates after the introduction of the dummy poly-Si structures 410. The metal used for the full silicidation of the gate electrode may be different from or the same as the metal used for the formation of the source and drain silicided regions. In the preferred embodiment, the metal used for the full silicidation of the gate electrode is nickel. The metal may also be cobalt, copper, molybdenum, titanium, tantalum, tungsten, erbium, zirconium, platinum, combinations thereof, or combinations thereof and nickel. Other metals may also be found useful after routine experimentation.

The silicidation may be effected, for example, by a high temperature anneal with a temperature in the range of about 200 degrees Celsius to about 900 degrees Celsius. The anneal can be performed in an inert ambient comprising nitrogen, helium, argon, neon, or other inert gasses. The annealing time can range from about 1 microsecond to several minutes. For example, in one embodiment in which nickel is used in the silicidation process and the amount of desired silicidation is about 200 to about 2000 angstroms in thickness, a high temperature anneal may be in the range of about 300 to about 700 degrees Celsius for several minutes.

FIG. 4d illustrates the wafer of FIG. 4c after the silicidation process is complete and excess metal has been removed. As one of ordinary skill in the art will appreciate, the resulting wafer has a substantially uniform surface and silicidation of the gate electrodes 314 is substantially uniform.

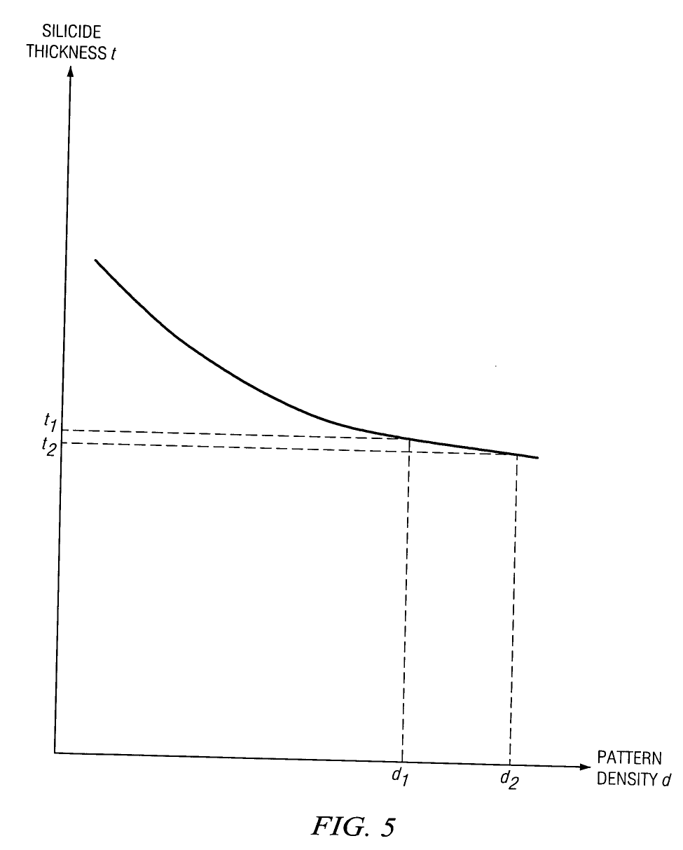

Referring now to FIG. 5, the silicide thickness t formed after a predetermined silicidation time is plotted as a function of the poly-Si pattern density d. FIG. 5 illustrates that a region with a lower poly-Si pattern density will have a thicker silicide thickness. By introducing dummy poly-Si structures and limiting the poly-Si structure density across the semiconductor substrate to the range of between d, and d₂, the silicide thickness formed will be in a small thickness range of between t₁ and t₂. In one embodiment, slight over-silicidation is performed, so that t₁ or t₂ is about 10% larger than the initial thickness of the poly-Si gate electrode prior to silicidation. In another embodiment, t₂ is approximately about 10% larger than the initial thickness of the poly-Si gate electrode prior to silicidation, and ti is approximately about 20% larger than the initial thickness of the poly-Si gate electrode prior to silicidation.

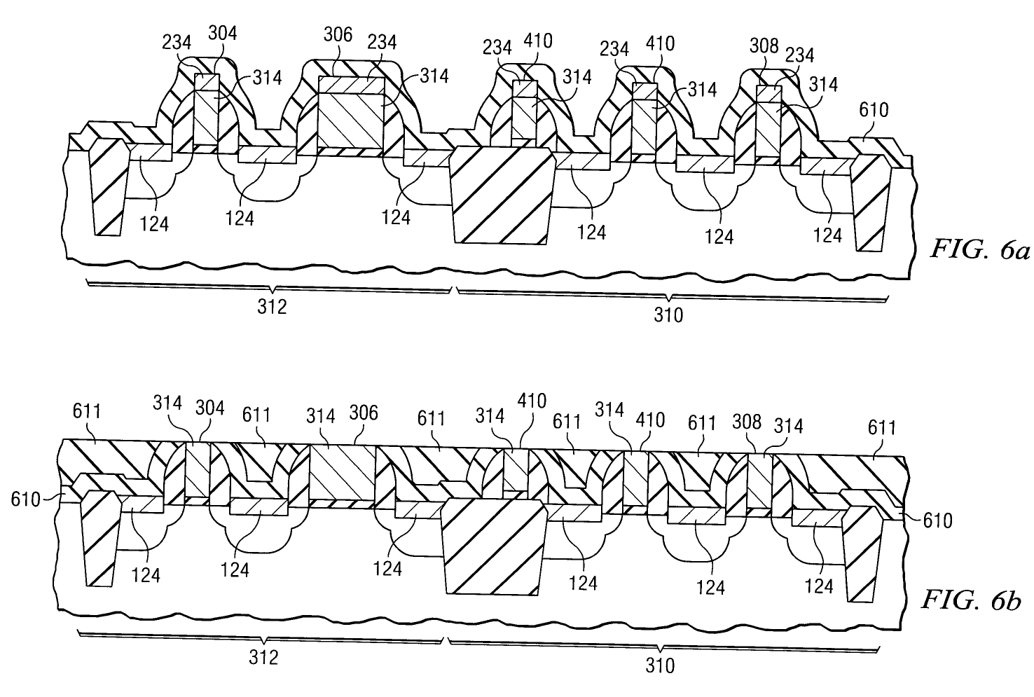

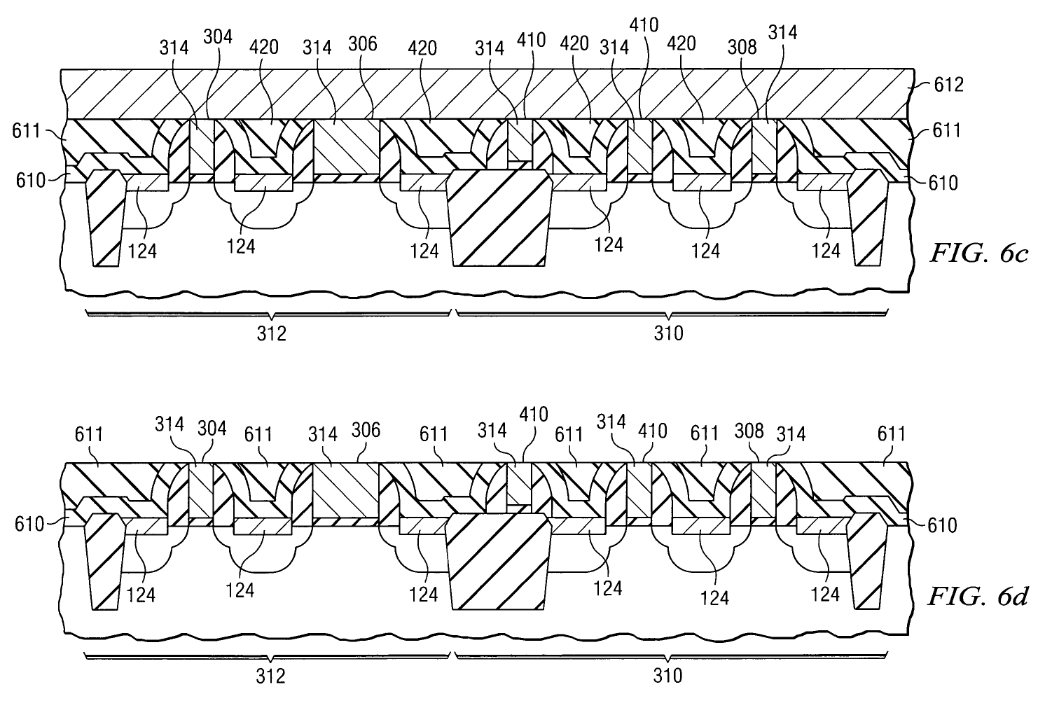

FIGS. 6a-6d illustrate a second method embodiment of the present invention in which an etch-stop layer is formed over the transistors prior to deposition of a dielectric layer and prior to full gate silicidation. The process begins in FIG. 6a wherein a wafer is provided as described above with reference to FIG. 3a, and an etch stop layer 610 is formed. The etch-stop layer 610 preferably comprises a material with a different chemical property from that of the dielectric layer such that an etchant with a high etch selectivity may be used. For example, if the dielectric layer is silicon oxide or a low permittivity (low-k) dielectric, the etch-stop layer 610 may comprise silicon nitride. After the formation of an etch-stop layer 610, a dielectric layer 611 is deposited and planarized, as shown in FIG. 6b.

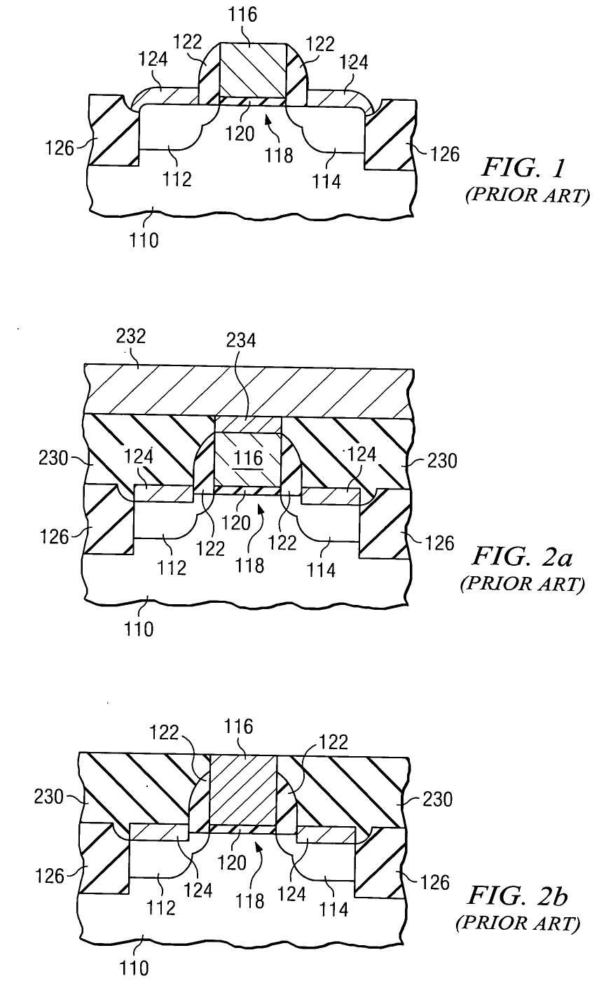

FIG. 6c illustrates the wafer of FIG. 6b after a metal layer 612 has been formed. The metal layer 612 may be formed, for example, as discussed above with reference to FIG. 4c. Annealing in an inert ambient as discussed above with reference to FIG. 4c results in full silicidation of the gate electrodes 314, as illustrated in FIG. 6d wherein the silicidation front 614 is located at the junction of the gate electrode 314 and the dielectric layer 120 (FIG. 1). Note that the remaining metal layer is removed, as shown in FIG. 6d.

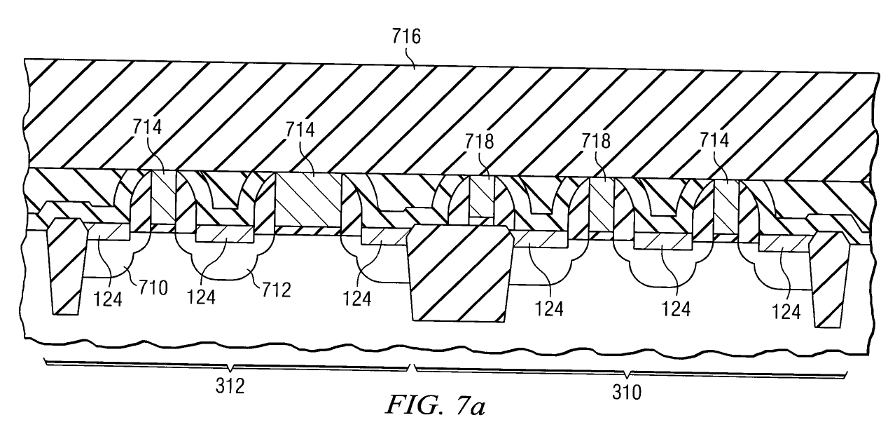

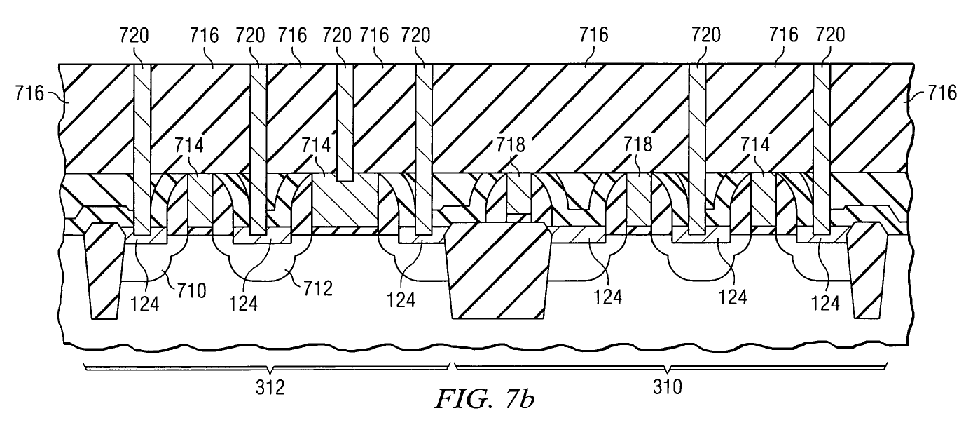

FIGS. 7a-7b illustrate another embodiment of the present invention wherein contacts are formed to the source 710, the drain 712, and the gate electrode 714 of select transistors. The process begins in FIG. 7a wherein a passivation layer 716 is formed over the transistors with silicided gate electrodes. Contacts 720 are etched through the passivation layer 716 to reach the silicided gate electrodes as illustrated in FIG. 7b. Some contacts 720 may be formed through the dielectric layer and the contact etch-stop layer (if present) to reach the silicided source/drain regions. Subsequently, metal interconnects (not shown) are formed overlying dielectric layer 716, as is known in the art.

In the foregoing specification, the invention has been described with reference to specific embodiments. However, various modifications and changes can be made by one skilled in the art without departing from the scope of the present invention. Accordingly, the specification and figures are to be regarded in an illustrative rather than a restrictive sense, and all such modifications are intended to be included within the scope of the present invention.

Although particular embodiments of the invention have been described in detail, it is understood that the invention is not limited correspondingly in scope, but includes all changes, modifications, and equivalents coming within the spirit and terms of the claims appended hereto. For example, different organization of structures and other types of structures may be used, varying thicknesses of the gate layer and gate insulator layer may be used, and the like. Accordingly, it is understood that this invention may be extended to other structures and materials, and thus, the specification and figures are to be regarded in an illustrative rather than a restrictive sense.

1. A semiconductor chip comprising:
a semiconductor substrate comprising an active region;
a first structure formed in the active region, the first structure being fully silicided; and
at least one dummy silicide structure.

2. The semiconductor chip of claim 1 wherein the first structure is a transistor gate electrode of a transistor.

3. The semiconductor chip of claim 2 wherein the transistor further comprises a gate dielectric underlying the first structure, the gate dielectric comprising a high permittivity dielectric selected from the group consisting of aluminum oxide, hafnium oxide, hafnium oxynitride, hafnium silicate, zirconium oxide, zirconium oxynitride, zirconium silicate, yttrium oxide, lanthalum oxide, cerium oxide, titanium oxide, and tantalum oxide.

4. The semiconductor chip of claim 1 wherein the dummy silicide structure is located in the active region.

5. The semiconductor chip of claim 1 wherein the dummy silicide structure is located in an isolation region separate from the active region.

6. The semiconductor chip of claim 1 wherein the first structure and dummy silicide structure each comprises nickel silicide.

7. The semiconductor chip of claim 1 wherein the first structure and dummy silicide structure each comprises a silicide of a material selected from the group consisting of nickel, cobalt, copper, molybdenum, titanium, tantalum, tungsten, erbium, zirconium, and platinum.

8. The semiconductor chip of claim 1 wherein the first structure and dummy silicide structure each comprises germanium.

9. The semiconductor chip of claim 1 wherein the semiconductor substrate is a silicon substrate.

10. The semiconductor chip of claim 1 wherein the semiconductor substrate is a semiconductor-on-insulator substrate.

11. The semiconductor chip of claim 1 further comprising a contact etch-stop layer overlying portions of the first structure.

12. The semiconductor chip of claim 1 further comprising a dielectric layer overlying the first structure and dummy silicide structure.

13. An integrated circuit chip comprising:
a substrate having an active region and an isolation region;
a transistor formed on the active region, the transistor having a source region, a drain region, and a fully silicided gate electrode; and
at least one dummy silicide structure.

14. The integrated circuit chip of claim 13 wherein electrical contacts are electrically coupled to the source region, the drain region, and the fully silicided gate electrodes.

15. The integrated circuit chip of claim 13 wherein the dummy silicided structure is located in the active region.

16. The integrated circuit chip of claim 13 wherein the dummy silicided structure is located in the isolation region.

17. The integrated circuit chip of claim 13 wherein the fully silicided gate electrode and dummy silicided structure comprise nickel silicide.

18. The integrated circuit chip of claim 13 wherein the fully silicided gate electrode and dummy silicided structure comprise a silicide of a material selected from the group consisting of nickel, cobalt, copper, molybdenum, titanium, tantalum, tungsten, erbium, zirconium, and platinum.

19. The integrated circuit chip of claim 13 wherein the fully silicided gate electrode and dummy silicided structure comprise germanium.

20. A method of forming a semiconductor device having a fully silicided structure, the method comprising the steps of:
providing a substrate having an active region and an isolation region;
forming a first polysilicon structure on the substrate;
forming a dummy polysilicon structure on the substrate, the dummy polysilicon structure being an inoperative circuit element;
forming a metal layer over the first polysilicon structure and the dummy polysilicon structure; and
siliciding first polysilicon structure and the dummy polysilicon structure with the metal layer to form a first fully silicided structure and a fully silicided dummy structure.

21. The method of claim 20 wherein the first polysilicon structure is a gate electrode of a transistor.

22. The method of claim 20 wherein the first polysilicon structure is located in the active region.

23. The method of claim 20 wherein the dummy polysilicon structure is located in the inactive region.

24. The method of claim 20 wherein forming the metal layer includes:
forming a dielectric layer over the first polysilicon structure and the dummy polysilicon structure; and
planarizing the dielectric layer such that the first polysilicon structure and the dummy polysilicon structure are exposed.

25. The method of claim 20 wherein the step of siliciding is performed by annealing at a temperature of about 200° C. to about 900° C. in an ambient comprising nitrogen, helium, argon, or neon.

26. The method of claim 20 wherein the step of forming the dummy silicided structure is performed by forming the dummy silicided structure in the active region.

27. The method of claim 20 the step of forming the dummy silicided structure is performed by forming the dummy silicided structure in the isolation region.

28. The method of claim 20 wherein the first fully silicided structure and the dummy silicided structure comprise nickel silicide.

29. The method of claim 20 wherein the first fully silicided structure and the dummy silicided structure comprise a silicide of a material selected from the group consisting of nickel, cobalt, copper, molybdenum, titanium, tantalum, tungsten, erbium, zirconium, and platinum.

30. The method of claim 20 wherein the first fully silicided structure and the dummy silicided structure comprise germanium.

31. The method of claim 20 wherein the step of forming the first polysilicon structure and the step of forming the dummy polysilicon structure are performed in the same process step.

32. The method of claim 20 wherein the dummy polysilicon structure is not electrically coupled to an active circuit element.

33. The method of claim 20 wherein the first polysilicon structure is a gate of a transistor.

34. A method of forming a transistor with fully silicided gate electrode, the method comprising the steps of:
providing a substrate having an active region and an isolation region;
forming a gate dielectric over the substrate;
forming a gate electrode and a dummy electrode over the gate dielectric, the gate electrode and the dummy electrode comprising silicon, the dummy electrode being an inactive circuit element;
forming source and drain regions oppositely adjacent the gate electrode to form a transistor;
depositing metal over the gate electrode and dummy electrode; and
siliciding the gate electrode and the dummy electrode with the metal to form a fully silicided gate electrode and a fully silicided dummy electrode.

35. The method of claim 34 wherein the gate electrode is located in the active region.

36. The method of claim 34 wherein the dummy electrode is located in the isolation region.

37. The method of claim 34 wherein depositing metal includes:
forming a dielectric layer over the gate electrode and the dummy electrode; and
planarizing the dielectric layer such that the gate electrode and the dummy electrode are exposed.

38. The method of claim 34 wherein the step of siliciding is performed by annealing at a temperature of about 200° C. to about 900° C. in an ambient comprising nitrogen, helium, argon, or neon.

39. The method of claim 34 wherein the fully silicided gate electrode and the fully silicided dummy electrode comprise nickel silicide.

40. The method of claim 34 wherein the fully silicized gate electrode and the fully silicized dummy electrode comprise a silicide of a material selected from the group consisting of nickel, cobalt, copper, molybdenum, titanium, tantalum, tungsten, erbium, zirconium, and platinum.

41. The method of claim 34 wherein the fully silicided gate electrode and the fully silicized dummy electrode comprise germanium.

42. The method of claim 34 wherein the step of forming the gate electrode and the dummy electrode are performed in the same process step.

43. The method of claim 34 wherein the dummy electrode is not electrically coupled to an active circuit element.
